(19) United States
(12) Patent Application Publication
(10) Pub. No.: US 2007/0127198 A1
(43) Pub. Date: Jun. 7, 2007

(54) Plasma display module

(76) Inventor: In-Soo Cho, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/633,726

(22) Filed: Dec. 5, 2006

(30) Foreign Application Priority Data
Dec. 6, 2005 (KR) 10-2005-0117844

(51) Int. Cl. G06F 1/16; H05K 5/00; H05K 7/00

(52) U.S. Cl. 361/681; 361/679

(57) ABSTRACT

A plasma display module having a reinforced strength to protect against damage from an external force is disclosed. In one embodiment, the plasma display module includes a plasma display panel where images are displayed, a chassis base that is coupled to the plasma display panel and is formed in a curved shape which curves away from the plasma display panel and a driving circuit unit that is supported by the chassis base and drives the plasma display panel.

### CROSS-REFERENCE TO RELATED PATENT APPLICATION

This application claims the benefit of Korean Patent Application No. 10-2005-0117844, filed on Dec. 6, 2005, in the Korean Intellectual Property Office, the disclosure of which is incorporated herein in its entirety by reference.

### BACKGROUND OF THE INVENTION

1. Field of the Invention

The present invention relates to a plasma display module, and more particularly, to a plasma display module with a structure having a reinforced strength to protect against damage from an external impact.

2. Description of the Related Art

Plasma display modules are flat panel display modules that display images by using a discharge effect. Because of their very good characteristics, such as high display capacity, high brightness, high contrast, enhanced performance, minimized or free of after-images, wide viewing angles, slim structure, and large screen size, plasma display devices are considered to be the next generation display devices which will replace cathode ray tubes (CRTs).

### SUMMARY OF CERTAIN INVENTIVE ASPECTS

One aspect of the present invention provides a plasma display module that has an improved structure suitable to manufacture a lightweight and thin plasma display module and that has an improved strength to protect against damage from an external impact.

Another aspect of the present invention provides a plasma display module that does not have a brightness difference or a color band phenomenon in addition to the above advantages.

Another aspect of the present invention provides a plasma display module comprising: a plasma display panel where images are displayed, a chassis base that is coupled to the plasma display panel and is formed in a curved shape which curves away from the plasma display panel and a driving circuit unit that is supported by the chassis base and drives the plasma display panel.

Still another aspect of the present invention provides a plasma display module comprising: i) a plasma display panel where images are displayed, ii) a chassis base that comprises coupling units which are formed at upper and lower extremities of the chassis base and are formed in a flat plate shape to provide a flat attaching surface that tightly contacts the plasma display panel and a curved unit which is formed in a curved shape and curves away from the plasma display panel between the coupling units and iii) a driving circuit unit which is supported by the chassis base and drives the plasma display panel, wherein the chassis base which comprises the coupling units and the curved unit is integrally formed as one unit.

Still another aspect of the present invention provides a plasma display module comprising: i) a chassis base, ii) a plasma display panel that displays images in front of the chassis base and is supported by the chassis base and iii) a driving circuit unit that drives the plasma display panel and is supported by the chassis base disposed on a rear surface of the chassis base, wherein the chassis base comprises at least one curved unit which is formed in a curved shape and curves away from the plasma display panel.

### BRIEF DESCRIPTION OF THE DRAWINGS

FIG. 1 is an exploded perspective view of a typical plasma display module.

FIG. 2 is an exploded perspective view of a plasma display module according to an embodiment of the present invention.

FIG. 3 is a vertical cross-sectional view taken along line III-III of FIG. 2, and shows an internal stress state of a chassis base against an external force.

FIG. 4 is a vertical cross-sectional view of a comparative example to the cross-sectional view of FIG. 3, and shows a deformed state of a plasma display module due to an applied external force.

FIG. 5 is a perspective view of a modified version of the chassis base of the plasma display module of FIG. 2, according to an embodiment of the present invention.

FIG. 6 is an exploded perspective view of a plasma display module according to another embodiment of the present invention.

FIG. 7 is a vertical cross-sectional view taken along line VII-VII of FIG. 6, and shows forces applied to a chassis base of the plasma display module due to the weight of the plasma display module when the plasma display module is hung on a wall.

### DETAILED DESCRIPTION OF CERTAIN INVENTIVE EMBODIMENTS

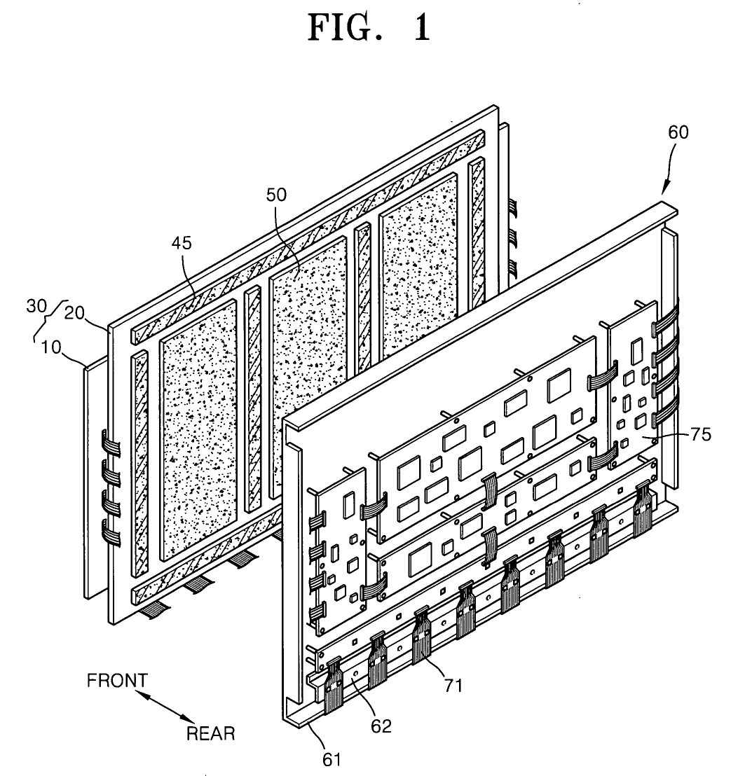

FIG. 1 is an exploded perspective view of a typical plasma display module. The plasma display module includes a plasma display panel 30 to display images and a chassis base 60 that supports the plasma display panel 30 disposed behind the plasma display panel 30. The panel includes a front panel 10 on which images are displayed and a rear panel 20 supported by the chassis base 60. Circuit substrates 75 that generate predetermined driving signals to be applied to the plasma display panel 30 are disposed on a rear surface of the chassis base 60. The driving signals generated by the circuit substrates 75 are transmitted to the plasma display panel 30 through connection cables 71.

Thermal conductive sheets 50 for transmitting heat generated during the operation of the plasma display panel 30 from the plasma display panel 30 to the chassis base 60 are interposed between the plasma display panel 30 and the chassis base 60. Each of the thermal conductive sheets 50 is attached to a different region of the plasma display panel 30 and is responsible for dissipating heat of the corresponding region. Strips of double-sided tape 45 that intermediate the coupling of the plasma display panel 30 with the chassis base 60 are attached to the plasma display panel 30 at outer areas of the plasma display panel 30 where the thermal conductive sheets 50 are not attached. In general, the adhesive strips of double-sided tape 45 have low thermal conductivity due to its material characteristics unlike the thermal conductive sheets 50 which have high thermal conductivity corresponding with the main purpose of the thermal conductive sheets 50 which is thermal conduction. Since outer areas of the plasma display panel 30 are non-discharge regions where no discharge occurs, the strips of double-sided tape 45 attached to the outer areas do not cause a heat dissipation problem, but since the central portion of the plasma display panel 30 corresponds to a discharge region where images are displayed a strip of double-sided tape 45 attached to a central portion of the plasma display panel 30 can be a cause of localized heat accumulation that can degrade the plasma display panel 30. For this reason, if a strip of double-sided tape 45 is attached to a discharge region of the plasma display panel 30, brightness is reduced resulting in a reduction of color definition, that is, a color band phenomenon can occur. Accordingly, there is a need to develop a new chassis base structure to be used when the strips of double-sided tape are removed to prevent the reduction of heat dissipation caused by the strips of double-sided tape.

The chassis base 60 serves as a heat dissipation plate that dissipates heat transferred from the plasma display panel 30 out of the plasma display module by natural air convection at an outer surface of the chassis base 60 and, at the same time, functions as a supporter that supports the plasma display panel 30 disposed in front of the chassis base 60 and the circuit substrates 75 disposed on the rear surface of the chassis base 60. Therefore, the chassis base 60 may need a mechanical strength greater than a predetermined level to safely protect the plasma display panel 30 and the circuit substrates 75 from an unexpected external impact. In a typical plasma display module, to manufacture the chassis base 60, a method of die-casting or pressing an aluminum material to a predetermined shape is used. Thus, the cost of raw materials for the plasma display module increases, thereby leading to high manufacturing costs. Also, the chassis base 60 formed of an aluminum material is susceptible to bending or twisting due to its material characteristics. Therefore, when an external impact is applied to the plasma display module during transportation or moving, the plasma display panel 30 and the circuit substrates 75 cannot be protected by the chassis base 60 but may be damaged by the external impact. In particular, as the size of the plasma display panel 30 increases, the size of the chassis base 60, which is proportional to the size of the plasma display panel 30, also increases, and therefore, becomes more susceptible to bending or twisting. Therefore, an additional reinforcing structure 61 or reinforcing member 62 for protecting the plasma display panel 30 is required.

In that situation, the thickness of the chassis base 60 formed of an aluminum material should be increased to ensure a predetermined strength. However, this increased thickness is disadvantageous for making a slim display module. Furthermore, the chassis base 60 formed of an aluminum material having a specific gravity of approximately 2.7 increases the total weight of the display module. Overall, the chassis base 60 formed of an aluminum material is a limiting factor for making a lightweight and thin plasma display module.

Recently, plastic materials are drawing attention as a new forming material of the chassis base since plastic materials are advantageous for making a lightweight yet strong and slim display module. But, plastic materials generally have a higher risk of brittleness than aluminum although a variation in performance according to the material characteristics of the specific plastic material used can be seen.

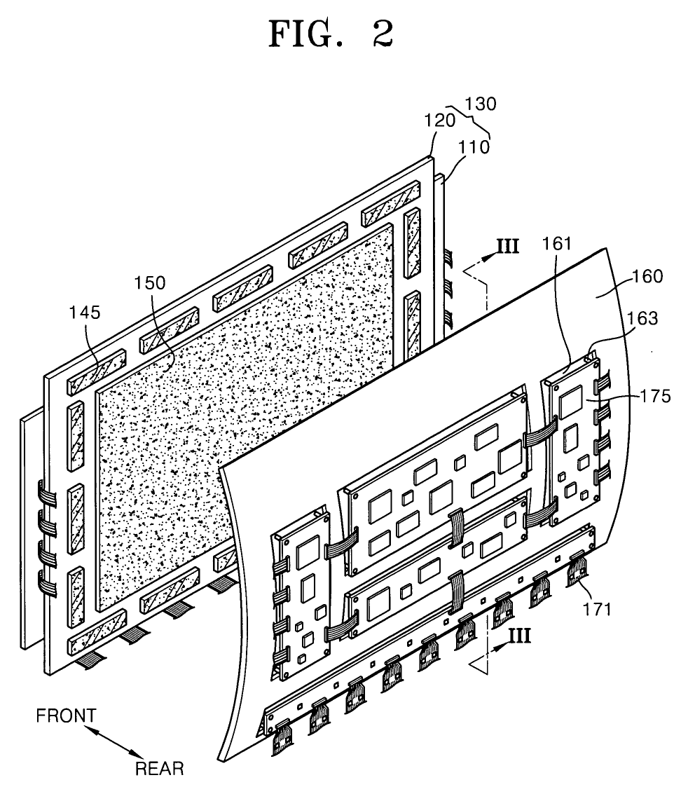

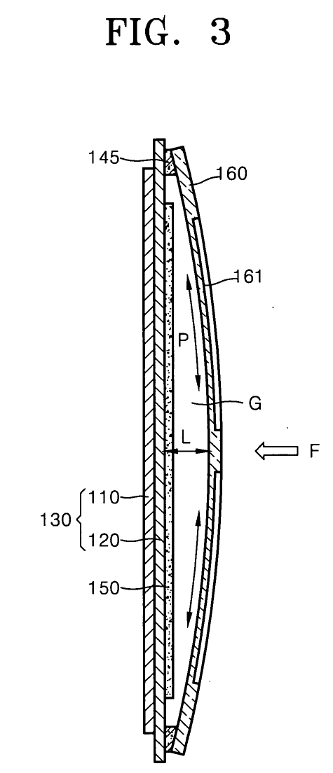

Embodiments of the present invention will now be described more fully with reference to the accompanying drawings in which exemplary embodiments of the invention are shown. FIG. 2 is an exploded perspective view of a plasma display module, according to an embodiment of the present invention, and FIG. 3 is a vertical cross-sectional view taken along line III-III of FIG. 2. The plasma display module includes a plasma display panel 130 forming a front portion of the plasma display module, a chassis base 160 disposed on a rear surface of the plasma display module, and a thermal conductive sheet 150 interposed between the plasma display panel 130 and the chassis base 160. The plasma display panel 130 includes a first panel 110 and a second panel 120 coupled to each other, and is an image display unit where images are displayed using a discharge. A plurality of discharge electrodes are disposed in the plasma display panel 130, and a plurality of circuit substrates 175 for supplying control signals and power to the plasma display panel 130 are disposed on a rear surface of the chassis base 160. The circuit substrates 175 generate a variety of different driving signals, and the generated driving signals are applied to the plasma display panel 130 through connection cables 171 which extend forward from the circuit substrates 175.

When operating, the plasma display panel 130 generates a large amount of heat. If the heat is not rapidly dissipated, the plasma display module, for example, a phosphor layer of the plasma display panel 130 (not shown) can be degraded, thereby reducing brightness. Accordingly, the thermal conductive sheet 150 having high thermal conductivity is attached to the plasma display panel 130 to rapidly dissipate the heat to the outside of the plasma display module. In a typical plasma display module, a multiple thermal conductive sheets are provided. In one embodiment, the thermal conductive sheet 150 is formed as one unit having a relatively large size and is attached to the entire display region of the plasma display panel 130. Therefore, the thermal conductive sheet 150 allows uniform heat dissipation over the entire display region and the structure of the plasma display module prevents brightness difference due to temperature variation of the plasma display panel 130.

Strips of double-sided tape 145 are attached to outer areas of the plasma display panel 130 where the thermal conductive sheet 150 is not attached. The strips of double-sided tape 145 are attached to the plasma display panel 130 along edges of the plasma display panel 130 corresponding to the structure of the thermal conductive sheet 150 provided in one unit, and are not disposed in a central portion of the display region. In this way, since the strips of double-sided tape 145 are excluded from the heat dissipation path, degradation of display quality due to heat accumulation can be prevented. The plasma display module is assembled by tightly coupling the plasma display panel 130 and the chassis base 160 with a pressure when the strips of double-sided tape 145 are interposed therebetween.

The chassis base 160 supports the plasma display panel 130 disposed in front of the chassis base 160 and the circuit substrates 175 disposed on a rear surface of the chassis base 160. In one embodiment, the chassis base 160 may be formed of a plastic material, for example, a thermoplastic resin material such as polypropylene, polyamide, etc., or thermosetting resin material such as phenol, epoxy, etc. Also, the chassis base 160 may be formed of a material comprising at least two different resins, or a material comprising a resin as a main component and additives as a functional material to obtain some properties such as moldability, strength, or heat-resistance. The chassis base 160 formed of a plastic material can be formed by, for example, injection molding. Since the plastic materials are relatively inexpensive, lightweight and have high strength and good moldability, when the chassis base 160 is formed of a plastic material, there are various advantages to forming the chassis base 160 of a plastic material, such as productivity of the plasma display modules can be increased, slim and lightweight plasma display modules can be produced, and the plasma display modules can be protected from external impacts since the resistance of plastic materials to bending and twisting is high.

In one embodiment, as shown in FIG. 2, the chassis base 160 has a cured shape, having a predetermined curvature, to reinforce strength against damage from an external force. On the chassis base 160, inlet units 161 having an approximately rectangular shape corresponding to a shape of the circuit substrates 175 and coupling bosses 163 protruded to a predetermined distance at each corner of the inlet units 161 are integrally formed for mounting the circuit substrates 175. Screw members (not shown) for fixing the circuit substrates 175 on a rear surface of the chassis base 160 are coupled to the coupling bosses 163. In one embodiment, the chassis base 160 has a dome shape. In another embodiment, the chassis base 160 is formed in a curved shape which curves away from the plasma display panel 130. In one embodiment, as shown in FIG. 3, since the chassis base 160 has a rounded shape with a predetermined curvature, the length L of the distance between the chassis base 160 and the plasma display panel 130 varies with the vertical position. In this embodiment, the length L gradually increases towards the vertical middle of the chassis base 160, and the length L is the maximum at the rounded portion of the vertical middle of the chassis base 160. In another embodiment, the chassis base 160 may have a variable curvature (e.g., multiple curvatures) which has a dome shape as a whole. In this embodiment, the length of the gap may be the maximum around a generally center area of the chassis base 160.

Since the strips of double-sided tape 145 that intermediate bonding between the chassis base 160 and the plasma display panel 130 are attached to the edges of the chassis base 160, the chassis base 160 can be directly supported by the strips of double-sided tape 145 when an external force is applied to the edges of the chassis base 160. Therefore damage to the chassis base 160 due to, for example, any brittleness can be prevented.

On the other hand, if, for example, an external force F is applied to a central portion of the chassis base 160 where a supporting member such as one of the strips of double-sided tape 145 is not attached, the external force F that is directed toward the front of the plasma display module acts to compress the chassis base 160 and creates an internal pressure P along the chassis base 160, and is transmitted to edges of the chassis base 160 along a cross-section of the chassis base 160. Accordingly, since the locally applied external force is distributed along a cross-section of the chassis base 160, damage to the chassis base 160 due to locally concentrated force and stress can be prevented by the structure of the plasma display module.

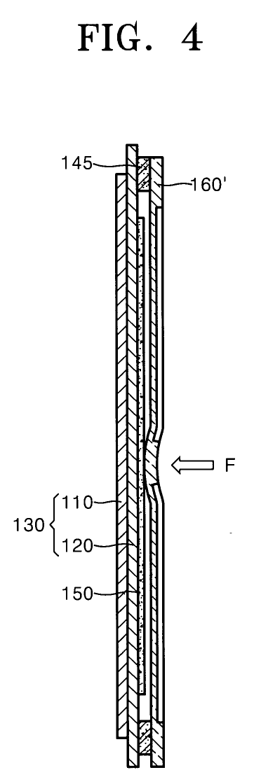

FIG. 4 shows a comparative example of a plasma display module having a chassis base 160′ that is not curved but is a flat plate. In this example, an external force F applied to a central portion of the chassis base 160′ is not distributed along the chassis base 160′ but is locally concentrated at an action point where the external force F is applied. In this case, if the action point is not a portion directly supported by a supporting member such as the double-sided tape 145, the surface of the chassis base 160′ may become deformed at the action point. When the external force F exceeds a critical limit of the material, the chassis base 160′ may be broken. In the example depicted in FIG. 3, the chassis base 160 has a rounded shape with a predetermined curvature, but the chassis base 160 according to embodiments of the present invention is not limited thereto. For example, the same technical aspect of the present invention as described above can be applied to a chassis base having a variable curvature along a vertical direction.

In one embodiment, since the chassis base 160 is formed in a curved shape which curves away from the plasma display panel 130, a predetermined space G is formed between the plasma display panel 130 and the chassis base 160. The thermal conductive sheet 150 can dissipate heat generated by the plasma display panel 130 by natural convection of air in the space G. More specifically, heat generated by the plasma display panel 130 is transferred to the thermal conductive sheet 150 attached to the plasma display panel 130, and the heat is dissipated into the air present in the space G from a surface of the thermal conductive sheet 150. At this time, to boost the heat dissipation effect through natural convection of air, it is desirable to allow low temperature air to flow into the space G from the exterior of the plasma display module. For this purpose, the strips of double-sided tape 145 attached to the plasma display panel 130 and the chassis base 160 may be attached at intermittent locations so that the space G is not entirely sealed. That is, the strips of double-sided tape 145 may be attached at intermittent locations instead of being attaching along entire outer areas of the chassis base 160. When the strips of double-sided tape 145 are attached at intermittent locations, low temperature air can flow into the space G from the exterior of the plasma display module, and high temperature air heated by heat transferred from the thermal conductive sheet 150 can flow out of the space G and the plasma display module. Air filled in the space G is heated by the thermal conductive sheet 150, becomes relatively hot and therefore will rise. Consequently, air of a lower temperature will be drawn into the space left by the raising hot air. Therefore an air-inlet and an air-outlet may be respectively formed in a lower side and an upper side of the chassis base 160 in consideration of the convection of air in the presence of a heat source.

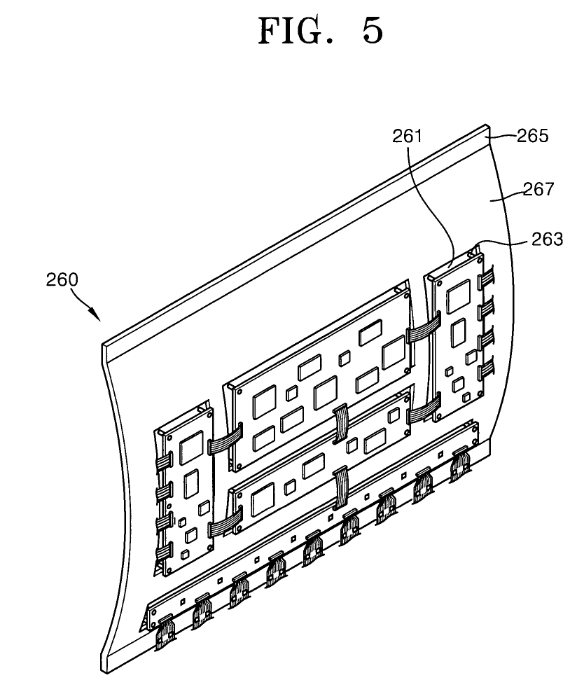

FIG. 5 is a perspective view of a modified version of the chassis base of the plasma display module of FIG. 2, according to an embodiment of the present invention. The chassis base 260 includes coupling units 265 which are formed at upper and lower extremities of the chassis base 260 and which are attached to a plasma display panel (not shown) and a curved unit 267 which is formed in a curved shape which curves away from the plasma display panel between the coupling units 265. The coupling units 265, as depicted in FIG. 5, are formed along upper and lower long side edges of the chassis base 260 and extend in a horizontal direction. In one embodiment, the coupling units 265 have a flat plate shape to provide a flat attaching surface that can tightly contact the plasma display panel. In this way, an attaching force between the plasma display panel and the chassis base 260 can be improved. In particular, the above method can be a solution for ensuring a sufficient attaching force in an embodiment in which the strips of double-sided tape 145 are not used at inner region of the plasma display panel.

The curved unit 267 which is formed in a curved shape which curves away from the plasma display panel between the coupling units 265 can distribute an external force concentrated on an action point over the entire curved unit 267. Therefore, the localized concentration of stresses and damage resulting from the localized concentration of the stresses can be prevented by the structure of the plasma display module. Also, a predetermined space can be formed between the plasma display panel and the chassis base 260 due to the curvature of the curved unit 267, thus heat generated from the plasma display panel can be dissipated out of the plasma display module by natural convection of air in the space formed therebetween.

In another embodiment, the coupling units 265 can also be formed along short side edges on left and right sides of the chassis base 260 extending in a vertical direction, or can be formed along both long and short side edges of the chassis base 260. An attaching structure of the strips of double-sided tape can be practically designed in consideration of appropriate attaching force and manufacturing convenience. Reference numerals 261 and 263 respectively indicate inlet units and coupling bosses for mounting circuit substrates on the chassis base 260.

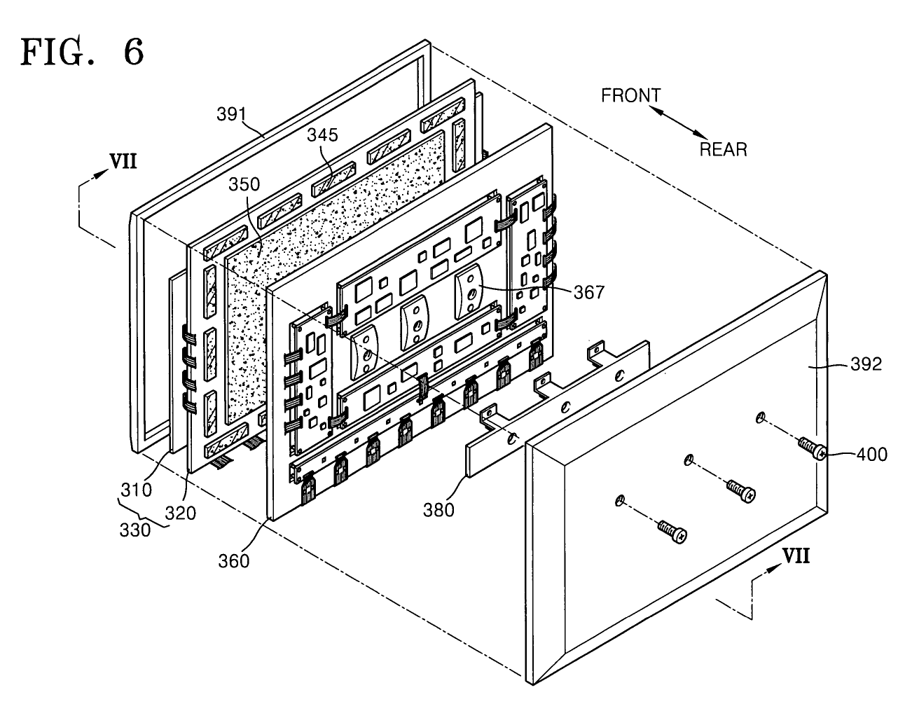

FIG. 6 is an exploded perspective view of a plasma display module according to another embodiment of the present invention. In FIG. 6, a front case 391 and a back case 392 coupled to each other to accommodate the plasma display module are shown. The plasma display module includes a plasma display panel 330, including two opposing panels 310 and 320, and a chassis base 360 facing the plasma display panel 330. In one embodiment, a thermal conductive sheet 350 formed as one unit and strips of double-sided tape 345 are disposed between the plasma display panel 330 and the chassis base 360 wherein the strips of double-sided tape 345 are intermittently attached to outer areas of the plasma display panel 330 where the thermal conductive sheet 350 is not attached. In one embodiment, parts of the chassis base 360 are curved instead of the entire chassis base 360 being curved. Curved units 367 are provided by forming portions of the chassis base 360 in a curved shape. The curved unit 367 are formed where a particular force will be applied, for example, where a wall hanging member 400 will be mounted. That is, the wall hanging member 400, for hanging an entire display device on a wall, is screw coupled to the curved unit 367 of the chassis base 360 through the back case 392. The fixed wall hanging member 400 is inserted into a fixing member (not shown) installed on the wall. In this case, the weight of the entire display device is concentrated on the curved unit 367 of the chassis base 360 where the wall hanging member 400 is mounted.

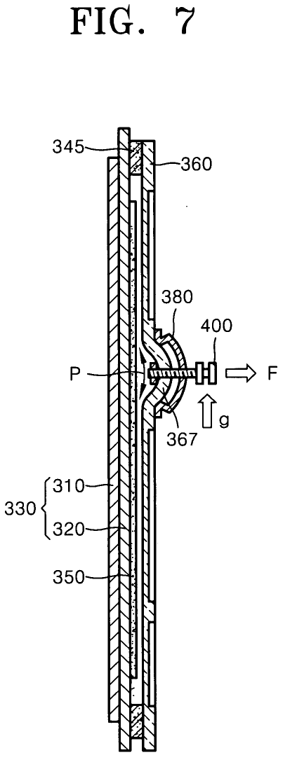

FIG. 7 is a vertical cross-sectional view taken along line VII-VII of FIG. 6, and schematically shows forces applied to the wall hanging member 400 of the chassis base 360 when the plasma display module is hung on a wall. Referring to FIG. 7, a gravitational weight g of the display device together with a rotational moment that tends to rotate the display device are applied to the wall hanging member 400. Accordingly, external forces in vertical and horizontal directions are applied to the wall hanging member 400. The horizontal external force F is transmitted to the chassis base 360 through the wall hanging member 400, causing a tension pressure P within the chassis base 360 and is further transmitted to edges of the chassis base 360 along a cross-section of the chassis base 360. The horizontal external force F transmitted to the edges of the chassis base 360 acts as a supporting force to hold the plasma display panel 330 on the wall through the strips of double-sided tape 345 of the edges of the chassis base 360.

If a chassis base of the plasma display module is formed as an entirely flat plate without considering the forces applied due to the weight of the plasma display module, the forces applied to the chassis base through a wall hanging member due to the weight of the plasma display module may not be distributed along a cross-section of the chassis base, but instead may locally concentrate on a portion where the wall hanging member is installed. Accordingly, there is a high risk of damage due to stress concentration. In FIG. 7, a wall hanging bracket 380 is installed on the curved unit 367 of the chassis base 360, and the wall hanging member 400 is screw coupled to the chassis base 360 through the wall hanging bracket 380. Here, the wall hanging bracket 380 distributes the external forces applied to the plasma display module due to the weight of the plasma display module over a wide area of the chassis base 360.

In a plasma display module according to at least one embodiment of the present invention, a chassis base is formed of an inexpensive plastic material having lightweight, high strength, and good moldability. Therefore, the productivity of the plasma display modules can be increased, slim and lightweight plasma display modules can be produced, and the plasma display modules can be sufficiently protected against damage from an external impact since plastic materials have high resistance to bending and twisting.

In one embodiment, a force concentrated on a local point is distributed along a cross-section of the chassis base by using a curved chassis base, thereby further reinforcing the structure of the chassis base. Furthermore, in embodiments of the present invention, brightness reduction due to the degradation of strips of double-sided tape in a discharge region of the plasma display panel can be prevented by not attaching the strips of double-sided tape in the discharge region. Furthermore, a supporting structural problem caused by not attaching the strips of double-sided tape in the discharge region of the plasma display panel is solved by employing a unique curved chassis base.

While the above description has pointed out novel features of the invention as applied to various embodiments, the skilled person will understand that various omissions, substitutions, and changes in the form and details of the device or process illustrated may be made without departing from the scope of the invention. Therefore, the scope of the invention is defined by the appended claims rather than by the foregoing description. All variations coming within the meaning and range of equivalency of the claims are embraced within their scope.

What is claimed is:

1. A plasma display module, comprising:
a chassis base configured to support a plasma display panel and formed in a curved shape which curves away from the plasma display panel.

2. The plasma display module of claim 1, wherein the chassis base is formed in a curved shape having a predetermined curvature.

3. The plasma display module of claim 1, further comprising i) a thermal conductive sheet formed as one unit attached to the entire display region of the plasma display panel where discharges are generated, and ii) strips of double-sided tape attached to outer areas of the plasma display panel where the thermal conductive sheet is not attached to intermediate coupling between the plasma display panel and the chassis base.

4. The plasma display module of claim 3, wherein the thermal conductive sheet is exposed to a space between the plasma display panel and the chassis base, and heat is dissipated through natural convection of air present in the space.

5. The plasma display module of claim 4, wherein the strips of double-sided tape are attached at intermittent locations to the plasma display panel having predetermined gaps between the strips of double-sided tape to allow air to flow in and out of the space between the plasma display panel and the chassis base.

6. The plasma display module of claim 1, wherein the chassis base is formed of a plastic material.

7. A plasma display module, comprising:
a plasma display panel configured to display images;
a chassis base including i) a curved unit having first and second ends, and ii) a pair of coupling units which are connected to both of the ends of the curved unit and configured to contact the plasma display panel, wherein the curved unit has a curvature and is curved along a direction which connects the first and second ends; and
a driving circuit unit supported by the chassis base and configured to drive the plasma display panel.

8. The plasma display module of claim 7, wherein each of the pair of coupling units is configured to provide a flat attaching surface that tightly contacts the plasma display panel.

9. The plasma display module of claim 7, wherein the coupling units are attached to the plasma display panel by strips of double-sided tape.

10. The plasma display module of claim 7, wherein the coupling units and the curved unit form an integral body.

11. A plasma display module, comprising:
a chassis base having first and second surfaces opposing each other;
a plasma display panel configured to display images and supported by a portion of the first surface of the chassis base; and
a driving circuit unit configured to drive the plasma display panel and supported by the second surface of the chassis base,
wherein the chassis base comprises at least one curved unit which curves away from the plasma display panel.

12. The plasma display module of claim 11, wherein the curved unit is formed in a curved shape having a predetermined curvature.

13. The plasma display module of claim 11, wherein the chassis base comprises at least one wall hanging member configured to hang the plasma display module on a wall, and the curved unit is provided in a region of the chassis base where the wall hanging member is fixed.

14. The plasma display module of claim 13, further comprising a wall hanging bracket installed on the curved unit of the chassis base, and the wall hanging member is screw coupled to the chassis base through the wall hanging bracket.

15. The plasma display module of claim 1, wherein the chassis base has a constant curvature.

16. The plasma display module of claim 1, wherein the chassis base has a variable curvature.

17. The plasma display module of claim 1, wherein the distance between the chassis base and the plasma display panel is the maximum around a generally center area of the chassis.

18. The plasma display module of claim 7, wherein the curvature is formed so as to curve away from the plasma display panel

19. The plasma display module of claim 7, wherein the distance between the chassis base and the plasma display panel varies along the direction.

20. The plasma display module of claim 7, further comprising strips of double-sided tape configured to couple outer areas of the plasma display panel and edges of the chassis base, wherein the outer areas of the plasma display panel belong to a non-display region where images are not displayed.
